(19) United States
(12) Patent Application Publication
(10) Pub. No.: US 2004/0080326 A1
(43) Pub. Date: Apr. 29, 2004

(54) Device and method for determining the sheet resistance of samples

(76) Inventors: Klaus Topp, Woerth-Hoerkofen (DE); Stefan Wurdack, Baldham (DE)

Correspondence Address: Welsh & Katz, Ltd., Eric D. Cohen, 22nd Floor, 120 South Riverside Plaza, Chicago, IL, 60606, US

(21) Appl. No.: 10/619,276

(22) Filed: Jul. 14, 2003

(30) Foreign Application Priority Data
Jul. 15, 2002 (DE) 102 31 989.8-52

(51) Int. Cl. G01R 27/08

(52) U.S. Cl. 324/724

(57) ABSTRACT

A device and method for determining the sheet resistance of samples, in particular wafers and other two-dimensional objects, comprising a means for measuring the conductivity of the sample according to the eddy current technique, wherein the sample is introducible into a gap for measurement, and comprising a means for measuring the position of the sample in the gap for measurement and a computing means for determining the sheet resistance on the basis of the measured conductivity and of the position of the sample in the gap for measurement.

The invention relates to a device and method for determining the sheet resistance of samples, in particular wafers and other two-dimensional objects.

A device and a method for determining the sheet resistance of a thin semiconductor layer by measuring the conductivity of the sample according to the eddy current technique is known from G. L. Miller et al., “Contactless measurement of semiconductor conductivity by radiofrequency-free-carrier power absorption” in Review of Scientific Instruments, Vol. 47, No. 7, July 1976, pages 799-805. It is described in this article that the power absorbed by a thin semiconductor layer in a magnetic oscillating field is proportional to the material conductivity.

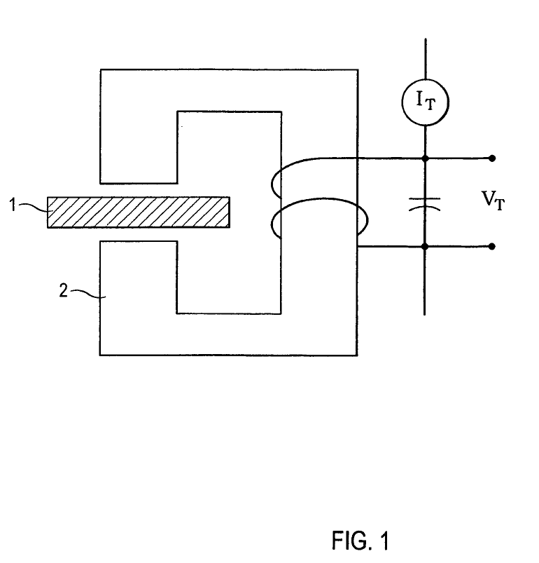

Eddy currents are generated in the conductive test object 1 (here a wafer) by the magnetic oscillating fields in the open oscillating circuit arrangement according to FIG. 1. These currents absorb power from the magnetic field. If an appropriate oscillator circuit is used which keeps the amplitude of the oscillating circuit constant, conclusions about the conductivity of the sample introduced can be drawn from the measurement of the varying current consumption of the oscillating circuit.

In a simplified manner, the relation between the sheet resistance R_{Square} (surface resistance) and the current variation ΔI upon introducing the sample is as follows:

$${R}_{Square} = \frac{K}{Δ I} , \qquad ( 1 )$$

wherein K is a constant of proportionality. Thus, the measured current variations are the higher the lower the impedance of the test object is.

It has turned out recently, that errors of measurement occur in this method, which can be determined by comparisons with the contacting four-point measurement of the sheet resistance.

The invention is based on the object to provide a device and a method for determining the sheet resistance of samples, in particular wafers and other two-dimensional objects more accurately and more reliably.

The object is achieved by the features contained in the claims.

According to the invention, the sheet resistance of samples is measured not only by determining the conductivity of the sample according to the eddy current technique but also by determining the position of the sample in the gap for measurement. Thus, it is possible to take into account the inhomogeneity of the magnetic field distribution in the gap for measurement and to increase the accuracy of the measurement by adjustments.

The simple and idealized relation (1) is significantly more complicated in reality since here the geometry-dependent influences of the respective set-up of the measurements are responsible for the measured values actually obtained. The relation between the sheet resistance R_{Square} and the measured current variation ΔI is as follows:

$${R}_{Square} = \frac{F ( z , d )}{Δ I} , \qquad ( 2 )$$

wherein F is a correction function which depends on the position z of the test object in the gap and on the thickness d of the test object. The measurement of the position and the thickness of the sample is preferably made in a contactless way, in particular by means of ultrasound, capacitive or optical techniques.

The correction function is preferably determined by calibrating the measurement equipment with a sample having a known sheet resistance. A correction value can be determined by measuring the position of the sample having a known thickness, using in said measurement the determined correction function. With the obtained correction value, the measurement result can be corrected.

The invention is exemplarily described in the following by means of specific embodiments with reference to the Figures without limiting the general concept of the invention, wherein

FIG. 1 schematically shows the known set-up for measuring the conductivity of the sample according to the eddy current technique,

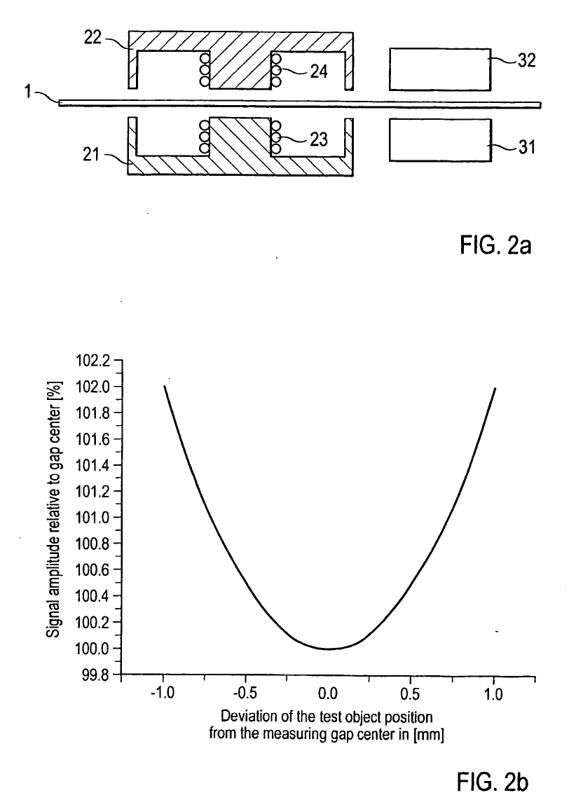

FIG. 2(a) schematically shows the device for determining the sheet resistance of the sample according to the present invention in a symmetrical arrangement, and FIG. 2(b) shows the typical dependence of the signal amplitude on the deviation of the position of the test object from the center of the gap for measurement in this arrangement,

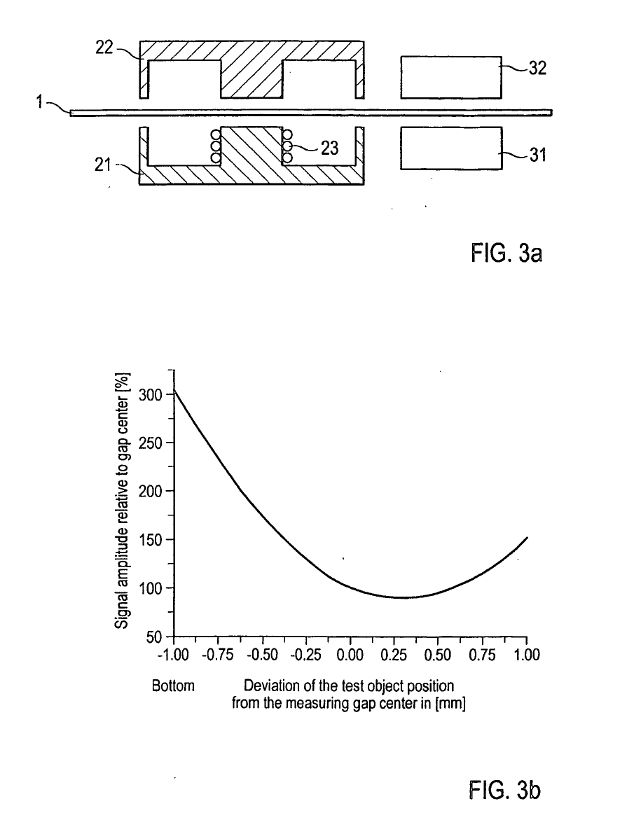

FIG. 3(a) schematically shows the device for determining the sheet resistance of the sample according to the present invention in an asymmetrical arrangement, and FIG. 3(b) shows the typical dependence of the signal amplitude on the deviation of the position of the test object from the center of the gap for measurement in this arrangement, and

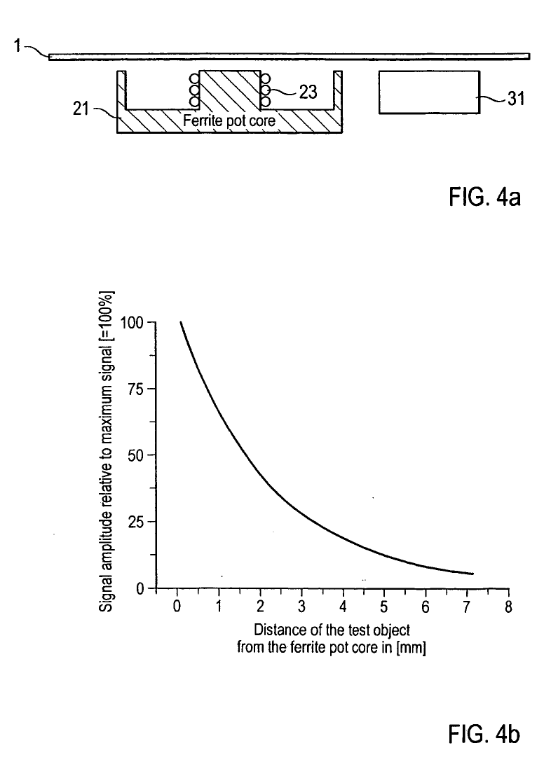

FIG. 4(a) schematically shows the device for determining the sheet resistance of the sample according to the present invention in a one-sided arrangement, and FIG. 4(b) shows the typical signal amplitude in dependence on the distance of the test object from a ferrite pot core.

FIG. 2(a) shows the symmetrical arrangement for determining the sheet resistance of a conductive sample 1. The sample 1 is in the gap for measurement which is formed between two ferrite pot cores 21, 22. Both ferrite pot cores are provided with coils 23, 24 serving the purpose of generating the magnetic oscillating field for the measurement of the sheet resistance according to the eddy current technique. Furthermore, FIG. 2(a) depicts sensors 31, 32 for measuring the position of the test object, which optionally can also be used for measuring the thickness. The distance between the location of the eddy current measurement and the sensors for the measurement of the position and/or the thickness preferably is approximately 1 cm.

The typical course of the signal amplitude in dependence on the position of the test object is illustrated in FIG. 2(b), wherein the signal amplitude is indicated in percent and amounts to 100% if the sample is in the center of the gap for measurement. The course of the signal amplitude is symmetrical relative to the central gap position and essentially exhibits a parabolic behavior. When the sample gets close to one of the pot cores, the signal amplitude rises, i.e. the power absorption increases, and the test object appears to have a lower impedance. The course of the curve shown in FIG. 2(b) usually changes in dependence on the thickness of the sample. When knowing the resultant family of curves (not shown) and with accurate information about the position and arrangement of the test object in the gap, an appropriate correction function can be indicated in dependence on the thickness of the test object by means of which it is then possible to correctly indicate the corrected resistance value independent of the position of the test object in the gap.

FIG. 3(a) shows the asymmetric arrangement for determining the sheet resistance of a sample 1. The arrangement corresponds to the one shown in FIG. 2(a) except that only the lower ferrite pot core 21 is provided with a coil 23. Hence, in this arrangement, only the lower ferrite pot core 21 becomes an active component of the oscillating circuit while the upper ferrite pot core 22 only serves the purpose of guiding the magnetic field lines so that they remain closed as far as possible. The advantage of this arrangement resides in that only one side comprises electronics. However, particularly large errors of measurement occur in the asymmetric arrangement without taking into account the position of the sample.

The one-sided excitation leads to a modified dependence of the test signal on the position of the sample, which is basically shown in FIG. 3(b). The signal amplitude in dependence on the deviation of the position of the test object from the center of the gap is indicated in percent, wherein the signal amplitude is 100% if the sample is in the center of the gap for measurement. The dependence of the signal amplitude on the deviation of the position of the test object from the center of the gap for measurement generally can be well described by a polynomial of a higher degree. The great influence of the position of the sample in the asymmetric arrangement is reflected in that in this example the signal amplitude approximately triples (300%) in case of a deviation of 1 mm from the center of the gap for measurement in the direction of the active, in this case the lower, ferrite pot core 21, while the value increases less, namely to 1.5 times the value (150%), in case of a deviation of also 1 mm in the other direction. With the symmetric arrangement, the increase in case of the same deviation is considerably lower and is in both directions only approximately to 102%.

FIG. 4(a) illustrates the one-sided arrangement for determining the sheet resistance of a conductive sample. The set-up is again similar to the one shown in FIG. 2(a) or FIG. 3(a), differing therefrom in that the one-sided arrangement comprises only one ferrite pot core 21 with a coil 23 and a sensor 31 for the measurement of the position of the sample. In this arrangement of the measurement set-up, the magnetic induction in the test object is generated by only one single ferrite pot core 21. It is preferred that there are no metallically conductive articles behind the test object since they could lead to a strong influence on the test signal. The advantage of this arrangement resides in that there is no fork-like arrangement of the ferrite cores. In particular in case of thin layers in which the position of the test object is known, it is thereby possible to enable the two-dimensional scanning of the sample by means of a simple X-Y mechanism. In the one-sided arrangement, the layer is preferably thin relative to the variation of the sensitivity of the means for measuring the conductivity. The one-sided arrangement is particularly suited for examining metal layers.

The typical dependence of the signal amplitude on the position of the sample is shown in FIG. 4(b). Since there is no longer any gap center, the signal amplitude is outlined as the distance of the test object from the ferrite core. The signal amplitude is indicated in percent, the signal amplitude of the maximum signal is 100%. The dependence of the signal amplitude on the distance of the test object from the ferrite pot core unambiguously has an exponential character.

In all three preferred embodiments, the position of the sample is preferably measured in a contactless way and the measurement can be performed in particular by means of ultrasound, capacitive or optical techniques. The position of the sample is measured in particular by determining the position of at least one of the two surfaces of the sample by measuring the distance of the at least one surface from the corresponding sensor for measuring the position and optionally the thickness of the sample. The measurement of the thickness of the sample 1 results in this case from the measurement of the distance of the lower and/or upper test object surface from the upper sensor 32 and/or the lower sensor 31, respectively, by comparison with the previously determined or defined distance of the two sensors 31, 32.

The families of curves required for correcting the measurement result are preferably determined by means of calibration measurements with various samples having known thicknesses and known sheet resistances, wherein the position of the sample in the gap for measurement is varied and the conductivity measured in each case is recorded. The thus determined correction functions can then be stored in the memory of a computing means which determines the sheet resistance of the sample on the basis of the measured conductivity and the thickness of the sample and the position of the sample in the gap for measurement. Preferably, the equation for the dependence between the position and the correction value and the respective coefficients are stored for each correction function.

1. A device for determining the sheer resistance of samples, in particular wafers and other two-dimensional objects, comprising a means for measuring the conductivity of the sample according to the eddy current technique, wherein the sample is introducible into a gap for measurement, and comprising a means for measuring the position of the sample in the gap for measurement and a computing means for determining the sheet resistance on the basis of the measured conductivity and of the position of the sample in the gap for measurement.

2. The device according to claim 1, wherein the means for measuring the position of the sample comprises a distance-measuring means which preferably operates in a contactless manner, in particular by means of ultrasound, capacitive or optical techniques.

3. The device according to claim 1 or 2, wherein the computing means comprises a memory in which a function is stored which is used in the calculation of the sheet resistance relative to the position of the sample in the gap for measurement.

4. The device according to claim 3, wherein coefficients of the function are stored in the memory which are specifically determined for the set-up of a device.

5. The device according to any one of claims 1 to 4, wherein the means for measuring the position of the sample acquires the position of the sample at least at two locations, preferably adjacent to and in particular at both sides of the location of the measurement of the conductivity, wherein preferably a pair of sensors are arranged at each location.

6. The device according to any of claims 1 to 5, comprising a means for determining the position of at least one of the two surfaces of a sample.

7. A method for determining the sheet resistance of samples, in particular wafers and other two-dimensional objects, comprising the steps of: measuring the conductivity of the sample according to the eddy current technique, wherein the sample is introducible into a gap for measurement, measuring the position of the sample in the gap for measurement and determining the sheet resistance on the basis of the measured conductivity and the position of the sample in the gap for measurement.

8. The method according to claim 7, wherein the step of measuring the position of the sample comprises a distance-measuring operation which is preferably performed in a contactless manner, in particular by means of ultrasound, capacitive or optical techniques.

9. The method according to claim 7 or 8, wherein the step of determining the sheet resistance uses a stored function and comprises a calculation of the sheet resistance relative to the position of the sample in the gap for measurement.

10. The method according to claim 9, comprising the step of using stored coefficients of said function which are specifically determined for the set-up of a device.

11. The method according to any one of claims 7 to 10, wherein the step of measuring the position of the sample is performed at least at two locations, preferably adjacent to and in particular at both sides of the location of the measurement of the conductivity.

12. The method according to any one of claims 7 to 11, comprising the step of determining the position of at least one of the two surfaces of a sample.
